(19) United States
(12) Patent Application Publication
(10) Pub. No.: US 2006/0011233 A1
(43) Pub. Date: Jan. 19, 2006

(54) Method for the post-treatment of a photovoltaic cell

(76) Inventors: Serdar Sariciftci, Linz (AT); Erhard Gloetzl, Linz (AT); Patrick Denk, Linz (AT); Roman Rittberger, Diersbach (AT); Franz Padinger, Austria (AU)

Correspondence Address: FISH & RICHARDSON PC, P.O. BOX 1022, MINNEAPOLIS, MN, 55440-1022, US

(21) Appl. No.: 10/509,935

(22) PCT Filed: Jun. 5, 2003
(86) PCT No.: PCT/AT03/00131

§ 371 Date: Aug. 19, 2005

(30) Foreign Application Priority Data
May 22, 2002 (AT) A 775/2002

(51) Int. Cl. H01L 31/00

(52) U.S. Cl. 136/290; 136/263

(57) ABSTRACT

The invention relates to a method for the post-treatment of a photovoltaic cell comprising a photoactive layer composed of two molecular components, specifically an electron donor and an electron acceptor, particularly a conjugated polymer component and a fullerene component, and two metal electrodes provided on either side of the photoactive layer, the photovoltaic cell being subjected to heat treatment above the glass transition temperature of the electron donor for a predetermined treatment time. To increase efficiency, it is proposed that the heat treatment of the photovoltaic cell be carried out for at least a portion of the treatment time under the influence of an electric field induced by a field voltage applied to the electrodes of the photovoltaic cell and exceeding the no-load voltage thereof.

### TECHNICAL FIELD

The invention relates to a method for the post-treatment of a photovoltaic cell comprising a photoactive layer composed of two molecular components, specifically an electron donor and an electron acceptor, particularly a conjugated polymer component and a fullerene component, and two metal electrodes provided on either side of the photoactive layer, the photovoltaic cell being subjected to heat treatment above the glass transition temperature of the electron donor for a predetermined treatment time.

### STATE OF THE ART

Synthetic materials known as conjugated synthetics, possessing an alternating sequence of single and double bonds, have energy bands that are comparable in terms of electron energy to those of semiconductors, and can therefore also be converted from the nonconductive to the metallically conductive state by doping. Examples of such conjugated synthetics are polyphenylenes, polyvinylphenylenes (PPV), polythiophenes and polyanilines. The energy conversion efficiency of photovoltaic polymer cells made of a conjugated polymer is typically between 10⁻³ and 10⁻²%, however. To improve this efficiency, it is known (U.S. Pat. No. 5,454,880 A) to make the photoactive layer from two molecular components, the one a conjugated polymer as the electron donor and the other a fullerene, particularly a Buckminsterfullerene (C₆₀), as the electron acceptor. The very fast electron motion induced by light at the interfaces between these components prevents more extensive charge-carrier recombination, thus bringing about a corresponding charge separation. This effective charge separation occurs only in the region of the interface between the electron donor and the electron acceptor, however, and efforts are therefore made to obtain the most uniform possible distribution of the fullerene components acting as electron acceptors in the polymer components constituting the electron donors.

Since it has been shown that electron mobility increases in a crystalline polymer matrix, compared to an amorphous matrix, and that crystallization increases at a temperature above the glass transition temperature, it has already been proposed to subject photovoltaic cells to post-treatment with heat in order to increase efficiency. To this end, photovoltaic cells were subjected to a treatment temperature of 60 to 150° C. for a treatment time of 1 h; however, the upper limit of efficiency proved to be about 3% and could not be increased further by optimizing the heat treatment.

### DESCRIPTION OF THE INVENTION

The object of the invention is, therefore, to devise a method for the post-treatment of a photovoltaic cell of the type described at the beginning hereof that permits a further increase in efficiency.

The invention achieves this object by the fact that the heat treatment of the photovoltaic cell is carried out for at least a portion of the treatment time under the influence of an electric field induced by a field voltage applied to the electrodes of the photovoltaic cell and exceeding the no-load voltage thereof.

The efficiency of the photovoltaic cell can be increased, in a surprising manner, via the influence of the electric field induced across the electrodes of the photovoltaic cell during the heat treatment. One possible explanation for this improvement in efficiency is that the electric field injects additional charge carriers into the photoactive layer across the electrodes. These additional charge carriers boost the alignment of the polymer components in the direction of the applied electric field; this requires that the polymer molecules possess a suitable mobility, which is obtained by heating the photovoltaic cell above the glass transition temperature of the polymer components. As the alignment of the polymer becomes stronger, its conductivity charge carrier conductivity increases. The electrical contacts between the electrodes and the photoactive layer are also gradually improved, thereby decreasing serial resistance inside the photovoltaic cell. Moreover, this decrease in serial resistance is accompanied by an increase in short-circuit current and fill factor.

In order for charge carriers to be injected into the photoactive polymer components via the electric field, the field voltage applied to the electrodes of the photovoltaic cell to induce the electric field must exceed the no-load voltage of the photovoltaic cell. To obtain a good effect, the field voltage must exceed the no-load voltage by at least 1 V. Especially favorable conditions are realized in most applications when the field voltage is selected to be between 2.5 and 3 V. The upper limit of the field voltage is limited intrinsically by the ability of the photovoltaic cell to withstand the applied electric field. And in any case, increasing the field voltage above the stated range of 2.5 to 3 V generally does not heighten directivity to the photoactive polymer components.

The positive influence of the heat treatment on the crystallization tendency of the photoactive polymer components diminishes after a given treatment time, and it is therefore advantageous to limit the time for which the photovoltaic cell is subjected to heat treatment under the influence of an electric field. Treatment times of between 2 and 8 min yield favorable conditions for heat treatment, with an optimum materializing when the treatment time is in the 4- to 5-min range.

### BRIEF DESCRIPTION OF THE DRAWING

The method according to the invention for the post-treatment of a photovoltaic cell is explained in greater detail with reference to the drawing. Therein:

FIG. 1 is a schematic section of a cell that is to undergo post-treatment,

FIG. 2 shows characteristic curves reflecting the relationship between voltage and current density for photovoltaic cells having basically the same structure, but without heat treatment, with heat treatment and with heat treatment under the influence of an electric field,

FIG. 3 reflects the charge yield per incident luminous power, referred to the wavelength of the photoexcitation, for photovoltaic cells of matching structure without and with heat treatment and with heat treatment under the influence of an electric field, and

FIG. 4 illustrates the dependence of the attainable efficiency of photovoltaic cells on the duration of heat treatment with and without the influence of an electric field.

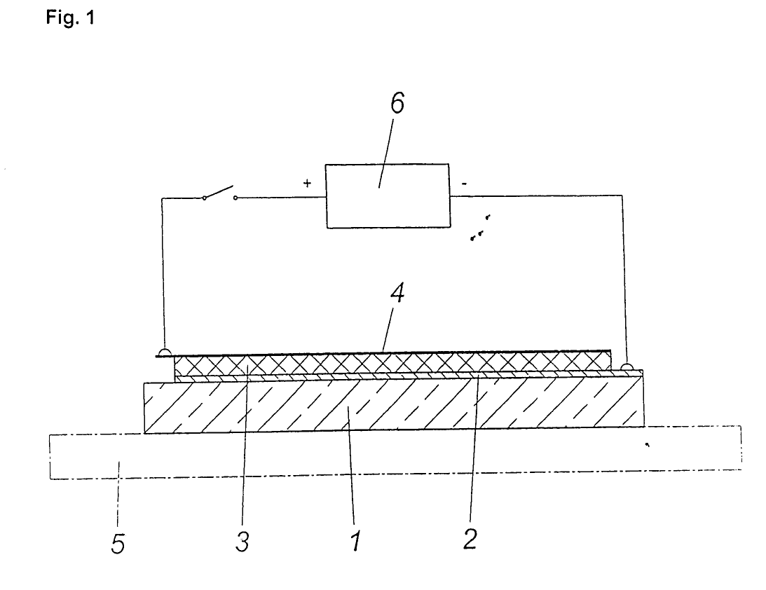

According to FIG. 1, the photovoltaic cell is composed of a transparent glass substrate 1 coated with an electrode 2 made of indium-tin oxide (ITO). Deposited on this electrode 2, which is generally covered with a smoothing layer of a polymer rendered electrically conductive by doping, usually polyethylene dioxythiophene (PEDOT), is a photoactive layer 3 made of two molecular components, specifically a conjugated polymer component and a fullerene component. Photoactive layer 3 in turn carries counterelectrode 4, which, when ITO is used as the hole-collecting electrode 2, is composed of an aluminum layer to form an electron-collecting electrode.

In the case of the exemplary embodiment the polymer component was a polythiophene, which provides excellent crystallization properties as a prerequisite for good hole conductivity. As the polythiophene, a poly-3-hexylthiophene (P3HT) with a methanofullerene, specifically [6,6]-phenyl C₆₁ butyl [sic] acid methyl ester (PCBM), was used as the electron acceptor. Deposited on ITO electrode 2, which had a layer thickness of 125 nm, was a layer of polyethylene dioxythiophene-polystyrene sulfonate (PEDOT-PSS) about 50 nm thick, after which, following a drying time of about 45 min, the photoactive layer was deposited under a vacuum of 10⁻¹ to 10⁻² mbar, specifically in the form of a solution of 10 mg P3HT and 20 mg PCBM per ml of solvent. The solvent used was 1,2-dichlorobenzene. After a drying time of about 45 min under a vacuum of 10⁻¹ to 10⁻² mbar, a layer of 0.6 nm lithium fluoride was first vapor-deposited, followed by the aluminum electrode in a layer thickness of 70 nm, in the same high-vacuum step (10⁻⁶ mbar).

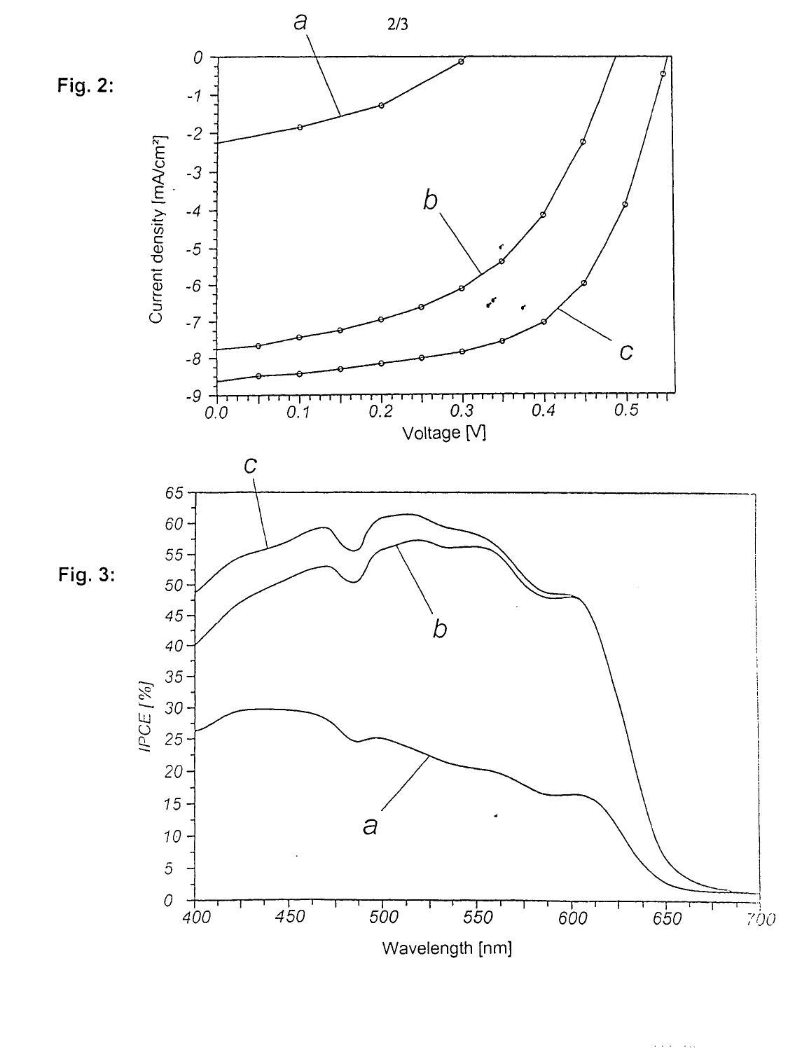

The photovoltaic cells fabricated in this manner were subjected to a post-treatment with heat, specifically in combination with an electric field. For this purpose, the photovoltaic cells were placed on a hot plate 5, electrodes 2 and 4 being connected to an electric voltage source 6. Between electrodes 2 and 4, to which a voltage of 2.7 V was applied, photoactive layer 3 was exposed to the influence of an electric field induced by this field voltage as soon as photoactive layer 3 was heated to a treatment temperature of between 70 and 75° C., i.e., a temperature above the glass transition temperature of the polymer components. The post-treatment was interrupted after a treatment time of 4 min. The photovoltaic cells cooled to ambient temperature. To visualize the effects that could be achieved by heating and the simultaneous induction of an electric field, the characteristic curves reproduced in FIGS. 2 and 3 were measured for identically constructed photovoltaic cells respectively undergoing no post-treatment and heat treatment without and with the influence of an electric field under the above-stated conditions.

The characteristic curves of FIG. 2 were recorded under illumination with white light (80 mW/cm²). Characteristic a, recorded for a photovoltaic cell with no post-treatment, shows a no-load voltage of 300 mV and a current density for the short-circuit current of about 2.5 mA/cm², with a fill factor of 0.4. The efficiency of these photovoltaic cells can be stated as about 0.4%. Characteristic b was recorded for a photovoltaic cell that had undergone post-treatment with heat only. In comparison to characteristic a, the no-load voltage increases to 500 mV and the density of the short-circuit current to about 7.5 m/cm². The fill factor was determined as 0.57. The efficiency of these photovoltaic cells was 2.5%. For photovoltaic cells subjected to heat treatment under the influence of an electric field, characteristic c shows a no-load voltage of about 550 mV and a short-circuit current density of about 8.5 mA/cm². With a fill factor of 0.6, an increase in efficiency to 3.5% is the result.

The charge yield per incident luminous power
IPCE [%]=1240·1ₖ/λ·1ₗ
over the wavelength λ, measured in nm, for the photovoltaic cells to be compared can be read from FIG. 3. 1ₖ introduces into the above formula the density of the short-circuit current, measured in μA/cm², and 1ₗ the luminous power, measured in W/m². It can be seen that the quantum efficiency IPCE [incident-photon-to-current conversion efficiency] for photovoltaic cells without post-treatment reaches a maximum of approximately 30% at a wavelength of 440 nm, as can be seen from characteristic a. In the case of heat-treatment without the influence of an electric field, the quantum efficiency IPCE nearly doubles, accompanied by a shift into a range of higher wavelengths, thus permitting better use of these wavelength ranges of solar radiation. Post-treatment with heat under the influence of an electric field brings about a further increase, as illustrated by characteristic c, resulting in a quantum efficiency IPCE of 61%.

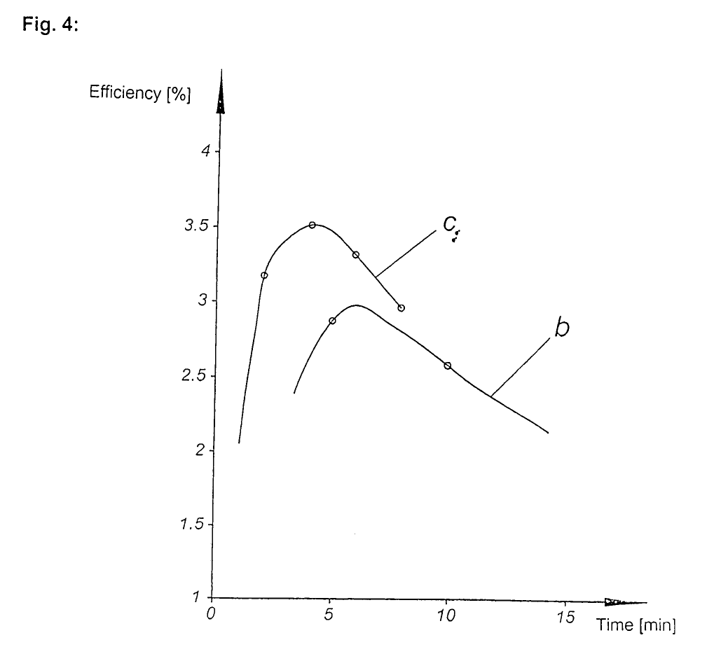

FIG. 4 represents the efficiency of photovoltaic cells having undergone heat treatment with and without the influence of an electric field as a function of treatment time. It is immediately apparent that efficiency varies with treatment time. For photovoltaic cells undergoing heat treatment without the influence of an electric field, an efficiency maximum is reached with a treatment time of around 6 min. Under the influence of an electric field, the maximum efficiency is found to occur with shorter treatment times on the order of about 4 min.

1. A method for the post-treatment of a photovoltaic cell, the photovoltaic cell comprising a photoactive layer and two metal electrodes, the photoactive layer comprising a conjugated polymer component and a fullerene component, and the two metal electrodes provided on either side of the photoactive layer, the method comprising:
subjecting the photovoltaic cell to heat treatment above a glass transition temperature of the conjugated polymer for a predetermined treatment time, the heat treatment of the photovoltaic cell being carried out for at least a portion of the treatment time under the influence of an electric field induced by a field voltage applied to the electrodes of the photovoltaic cell and exceeding a no-load voltage thereof.

2. The method according to claim 1, wherein the electric field is induced via a field voltage that exceeds the no-load voltage of the photovoltaic cell by at least 1 V.

3. The method according to claim 2, wherein the field voltage is between 2.5 and 3 V.

4. The method according claim 1, wherein the photovoltaic cell is subjected for between 2 and 8 min, to heat treatment under the influence of an electric field.

5. The method of claim 2, wherein the photovoltaic cell is subjected for between 2 minutes and 8 minutes to heat treatment under the influence of an electric field.

6. The method of claim 3, wherein the photovoltaic cell is subjected for of between 2 minutes and 8 minutes to heat treatment under the influence of an electric field.

7. The method of claim 1, wherein the photovoltaic cell is subjected for between 4 minutes and 4 minutes to heat treatment under the influence of an electric field.

8. The method of claim 2, wherein the photovoltaic cell is subjected for between 4 minutes and 5 minutes to heat treatment under the influence of an electric field.

9. The method of claim 3, wherein the photovoltaic cell is subjected for between 4 minutes and 5 minutes to heat treatment under the influence of an electric field.

10. A method of treating a photovoltaic cell, the method comprising:
heating the photovoltaic cell for a period of time; and
simultaneously subjecting the photovoltaic cell to an electric field,
wherein the photovoltaic cell comprises:
a first electrode;
a second electrode; and a photoactive layer between the first and second electrodes.

11. The method of claim 10, wherein the photoactive layer comprises an electron donor and an electron acceptor.

12. The method of claim 11, wherein the photovoltaic cell is heated to above a glass transition temperature of the electron donor.

13. The method of claim 10, wherein the electric field is formed by applying a field voltage to the first and second electrodes.

14. The method of claim 13, wherein the electric field exceeds a no-load voltage of the photovoltaic cell.

15. The method of claim 14, wherein the electric field exceeds the no-load voltage by at least 1V.

16. The method of claim 13, wherein the electric field is between 2.5V and 3V.

17. The method of claim 13, wherein the period of time is between 2 minutes and 8 minutes.

18. The method of claim 13, wherein the period of time is between 4 minutes and 5 minutes.

19. A method of treating a photovoltaic cell, the method comprising:
heating the photovoltaic cell for between 2 and 8 minutes; and
simultaneously subjecting the photovoltaic cell to an electric field,
wherein the photovoltaic cell comprises:
a first electrode;
a second electrode; and a photoactive layer between the first and second electrodes;
the electric field is formed by applying a field voltage to the first and second electrodes; and
the electric field exceeds a no-load voltage of the photovoltaic cell.

20. The method of claim 19, wherein the photoactive layer comprises an electron donor and an electron acceptor.

21. The method of claim 20, wherein the photovoltaic cell is heated to above a glass transition temperature of the electron donor.

22. The method of claim 19, wherein the electric field exceeds the no-load voltage by at least 1V.

23. The method of claim 19, wherein the photovoltaic cell is heated for between 4 minutes and 5 minutes.

24. A method of treating a photovoltaic cell, the method comprising:
heating the photovoltaic cell for a period of time; and
simultaneously injecting charge carriers into the photovoltaic cell,
wherein the photovoltaic cell comprises:
a first electrode;
a second electrode; and a photoactive layer between the first and second electrodes; and
the charge carriers are injected into the photovoltaic cell via at least one electrode selected from the group consisting of the first electrode and the second electrode.
